(19) United States
(12) Patent Application Publication
(10) Pub. No.: US 2005/0212144 A1
(43) Pub. Date: Sep. 29, 2005

(54) Stacked die for inclusion in standard package technology

(76) Inventors: William Leon Rugg, Longmont, CO (US); Robert William Warren JR., Loveland, CO (US); Chau-Chin Low, Fremont, CA (US)

Correspondence Address: David K. Lucente, Seagate Technology LLC;Intellectual Property - COL2LGL, 389 Disc Drive, Longmont, CO, 80503, US

(21) Appl. No.: 10/809,720

(22) Filed: Mar. 25, 2004

(51) Int. Cl. H01L 29/40

(52) U.S. Cl. 257/782

(57) ABSTRACT

Disclosed is a method and apparatus for stacking dice including multi-chip packaging with additional non stacked dice. The stacked dice have at least one electrical connection located on a single surface and oriented in the same direction when stacked. These dice are stacked, offset and coupled electrically. In an embodiment, the stacked dice have a buffer function, such as an SDRAM device, and are included in a multi-chip package (MCP) with an additional die including a channel function and a controller function thereon. The dice are packaged in a single package for placement on a printed circuit board for use in a storage device such as a disc drive.

### FIELD OF THE INVENTION

The present invention relates generally to semiconductor stacking and packaging. More particularly, the present invention relates to stacking chips for multi-chip packaging of storage device functions.

### BACKGROUND OF THE INVENTION

Modem disc drives are commonly used in a multitude of computer environments to store large amounts of data in a form that is readily available to an end user. A typical disc drive has one or more rigid magnetic recording discs that rotate at constant speed. The surface of each disc has a magnetic medium that can store magnetic data for later access by a read and write head dedicated to the surface. Much of the control and data handling, in addition to many other functions, are made possible by components such as IC (Integrated Circuit) chips located on a PCBA (Printed Circuit Board Assembly) attached to the disc drive. These chips usually include a controller for interfacing the disc drive with the rest of the computer system; a channel that communicates with the controller, and manages read and write functions; and a buffer that acts as a cache for the disc drive, such as an SDRAM (Synchronous Dynamic Random Access Memory). Such devices are typically fabricated using semiconductor processing technology such as VLSI (Very Large Scale Integration).

Traditionally, these integrated circuit chips are provided in computer systems using a single package per chip. For example, a buffer function provided by an SDRAM device is usually provided on one die while controller and channel functions are provided for on a separate die. If multiple chips are used to accomplish similar or identical tasks, these chips are also provided for on separate dice. In current computer systems, these separately packaged dice are placed separately on the PCBA.

There are several problems associated with mounting individual chips on a PCBA. A chip package is several times the area of the die itself, taking up more space on the circuit board. Circuit resistance is increased by the individual resistances of all the package pins and the electrical path lengths are multiplied by the number of chips and package leads. In current designs, the length traveled by the point-to-point signals and the number of connections required between these separate packages have enormous performance and system level implications, such as increased noise, and an increase in required signal strength due to the number of connections separating the relevant devices.

Another issue involves the reliability of the IC's placed on a PCBA. In individual package processes, a final test assures the quality of the completed product. If the chip is bad or the process faulty, the entire chip and package is discarded. But when packaging devices together, failure of one of the packaged dice means both must be discarded, adding to waste and increasing the overall cost because of lost good components shared in the package with bad components and the need to increase testing to prevent such loss.

One option is to rely on the results of a wafer-sort test to certify die performance. Unfortunately, wafer sort does not include environmental tests or long term reliability tests. Therefore, there is a need in the art for a reliable alternative to the multi-package solution for disc drive chips.

The present invention provides a solution to this and other problems, and offers other advantages over previous solutions.

### SUMMARY OF THE INVENTION

Embodiments of the present invention overcome various disadvantages and limitations of the prior art by stacking and combining semiconductor chip functions in one package.

Embodiments of the present invention may therefore comprise an apparatus comprising: at least two dice; each of the dice having at least one electrical connection disposed on a single surface; the dice are electrically coupled between the electrical connections that are oriented in the same direction when the dice are stacked and offset.

Embodiments of the present invention may further comprise a method comprising: placing a first die having electrical connections disposed on one surface in a first area of a package; applying an adhesive layer on the first die; aligning a second die having electrical connections disposed on one surface; orienting the electrical connections on both of the die in a same direction; offsetting the second die relative to the first die; placing the second die on the adhesive layer; electrically coupling the electrical connections that are oriented in the same direction on the first and the second die.

These and various other features as well as advantages which characterize embodiments of the present invention will be apparent upon reading of the following detailed description and review of the associated drawings.

### BRIEF DESCRIPTION OF THE DRAWINGS

FIG. 1 is a diagram of a computer system consistent with implementation of an embodiment of the present invention.

FIG. 2 shows a block diagram of functional parts of the computer system of FIG. 1.

FIG. 3 shows a hard disc drive system consistent with implementation of an embodiment of the present invention.

FIG. 4A shows a cross-sectional view of an embodiment of the present invention.

FIG. 4B shows a cross-sectional view of an embodiment with the electrical coupling of the stacked dice on an external location relative to the dice.

FIG. 4C shows a cross-sectional view of a third die stacked and offset relative to two other dice.

FIG. 5A shows a top plan view of the embodiment of FIG. 4A

FIG. 5B shows a top plan view of the connections of an embodiment of the stacked dice including a System on Chip controller and channel.

FIG. 6 shows an isometric view of the connections of FIG. 5B

FIG. 7 shows a flow chart of a method to assemble the present invention.

FIG. 8 shows a standard printed circuit board.

FIG. 9 shows a printed circuit board having a single multi-chip package, consistent with an embodiment of the present invention.

FIG. 10 shows a cutaway view of an innovative package according to an embodiment of the present invention.

FIG. 11 shows the innovative multi-chip package according to the embodiment of FIG. 5B.

### DETAILED DESCRIPTION

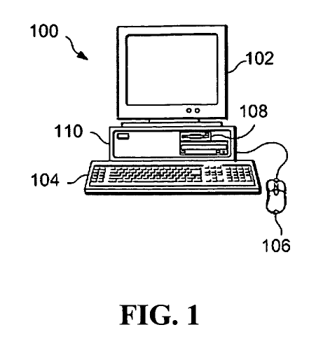

With reference now to the figures and in particular with reference to FIG. 1, a pictorial representation of a data processing system in which the present invention may be implemented is depicted in accordance with an embodiment of the present invention. In what follows, similar or identical structure is identified using identical callouts. A computer 100 is depicted which includes a system unit 110, a video display terminal 102, a keyboard 104, storage devices 108, which may include floppy drives and other types of permanent and removable storage media, and mouse 106. Additional input devices may be included with personal computer 100, such as, for example, a joystick, touchpad, touch screen, trackball, microphone, and the like. Computer 100 can be implemented using any suitable computer, such as an IBM RS/6000 computer or IntelliStation computer, which are products of International Business Machines Corporation, located in Armonk, N.Y. Although the depicted representation shows a computer, other embodiments of the present invention may be implemented in other types of data processing systems, such as a network computer. Computer 100 also preferably includes a graphical user interface that may be implemented by means of systems software residing in computer readable media in operation within computer 100.

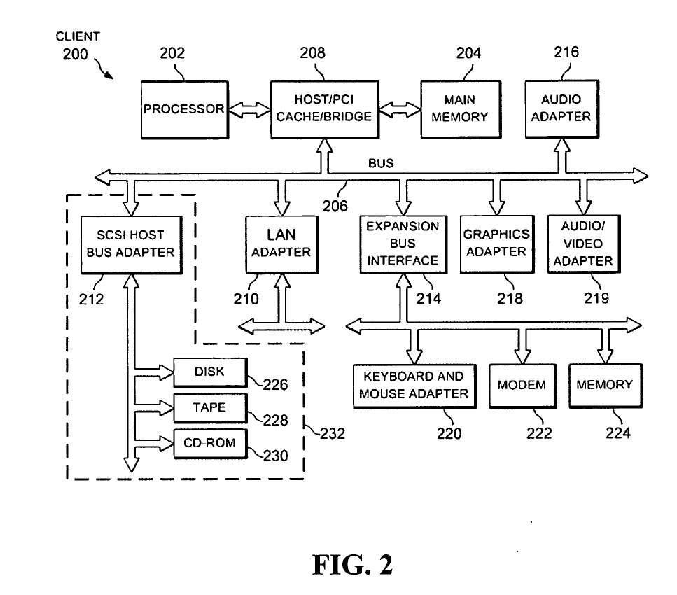

With reference now to FIG. 2, a block diagram of a data processing system is shown in which the present invention may be implemented. Data processing system 200 is an example of a computer, such as computer 100 in FIG. 1, in which code or instructions implementing the processes of the present invention may be located. Data processing system 200 employs a PCI (Peripheral Component Interconnect) local bus architecture. Although the depicted example employs a PCI bus, other bus architectures such as AGP (Accelerated Graphics Port) and ISA (Industry Standard Architecture) may be used. Processor 202 and main memory 204 are connected to PCI local bus 206 through PCI bridge 208. PCI bridge 208 also may include an integrated memory controller and cache memory for processor 202. Additional connections to PCI local bus 206 may be made through direct component interconnection or through add-in boards. In the depicted example, local area network (LAN) adapter 210, small computer system interface SCSI host bus adapter 212, and expansion bus interface 214 are connected to PCI local bus 206 by direct component connection. In contrast, audio adapter 216, graphics adapter 218, and audio/video adapter 219 are connected to PCI local bus 206 by add-in boards inserted into expansion slots. Expansion bus interface 214 provides a connection for a keyboard and mouse adapter 220, modem 222, and additional memory 224. SCSI host bus adapter 212 provides a connection for hard disc drive 226, tape drive 228, and CD-ROM drive 230. Typical PCI local bus implementations will support three or four PCI expansion slots or add-in connectors.

An operating system runs on processor 202 and is used to coordinate and provide control of various components within data processing system 200 in FIG. 2. The operating system may be a commercially available operating system such as Windows 2000, which is available from Microsoft Corporation.

Those skill in the art will appreciate that the hardware in FIG. 2 may vary depending on the implementation. Other internal hardware or peripheral devices, such as flash ROM (or equivalent nonvolatile memory) or optical disc drives and the like, may be used in addition to or in place of the hardware depicted in FIG. 2. Also, the processes of the present invention may be applied to a multiprocessor data processing system.

For example, data processing system 200, if optionally configured as a network computer, may not include SCSI host bus adapter 212, hard disc drive 226, tape drive 228, and CD-ROM 230, as noted by dotted line 232 in FIG. 2 denoting optional inclusion. In that case, the computer, to be properly called a client computer, must include some type of network communication interface, such as LAN adapter 210, modem 222, or the like. As another example, data processing system 200 may be a stand-alone system configured to be bootable without relying on some type of network communication interface, whether or not data processing system 200 comprises some type of network communication interface. As a further example, data processing system 200 may be a PDA (Personal Digital Assistant), which is configured with ROM and/or flash ROM to provide non-volatile memory for storing operating system files and/or user-generated data.

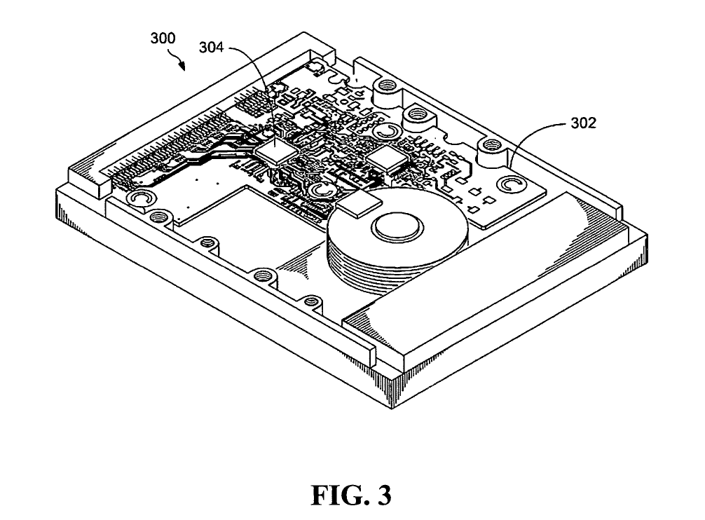

Referring now to FIG. 3, a general hard disc drive system is shown, consistent with implementation of an embodiment of the present invention. This example shows hard disc drive 300 in the form of a standard 95 mm HDD with BGA (Ball Grid Array) MCP 304. It is in this context that the present invention is preferably incorporated. Hard disc drive 300 is implemented, for example, as disc drive 226 in the above described computer system, but can serve different functions, such as storage in other types of information processing systems, such as a server.

Standard industry disc drive electronics are configured with individual packages for the individual die. The purposes are generally related to reliability issues. The disadvantages of this construct include measurable performance and system level noise implications due to the length of the point-to-point signal and number of connections between chips, in addition to the excessive area consumption on a PCBA 302. By stacking the chips, offsetting them, for ease of manufacturing, and packaging in an MCP, many of these problems are addressed.

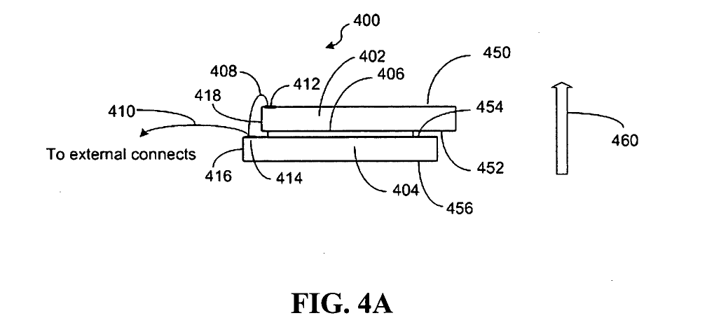

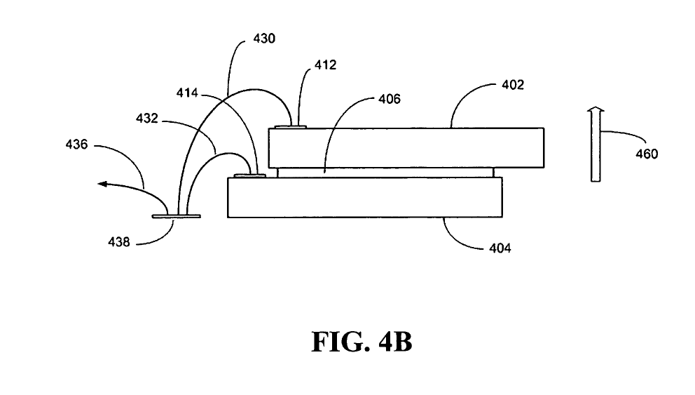

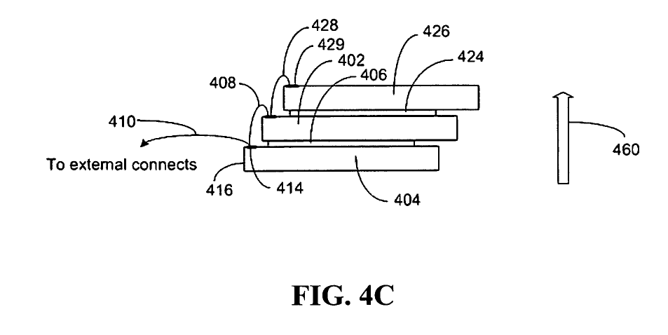

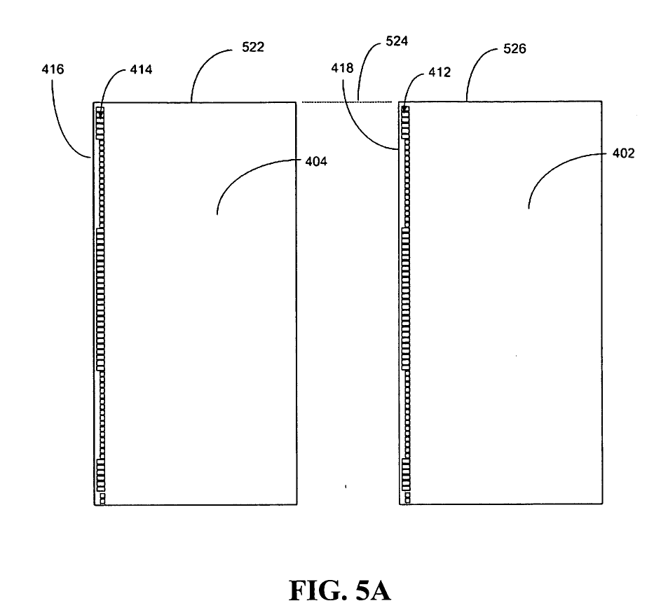

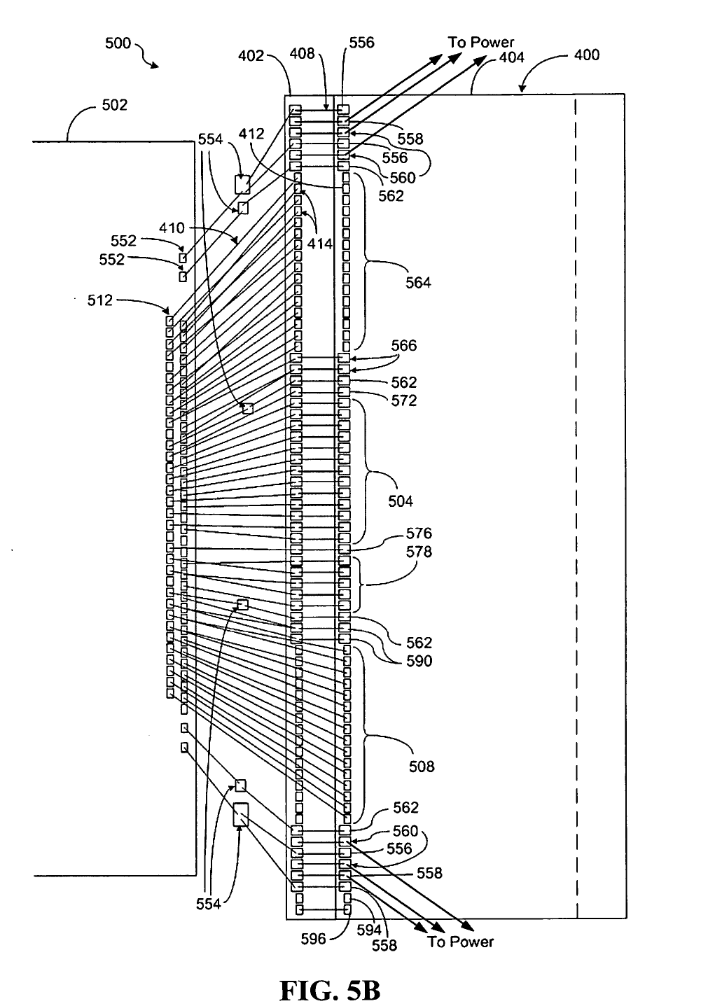

Referring now to FIG. 4A, in a cross sectional view of one embodiment, a first SDRAM 402 is stacked and offset relative a second SDRAM 404. In this embodiment the offsetting is shown where the leading edge 418 is offset relative to the leading edge 416. A first bonding pad 412 is coupled to a second bonding pad 414 with an electrical connection 408. The bonding pads 414 and 412 are on the top surfaces 450 and 454 of the SDRAMs 402 and 404 respectively and along the respective leading edges 416 and 418. The chips 402 and 404 are oriented such that the connection points 412 and 414 are in the same direction, or similar direction, and in this case in the direction 460. For purposes of orientation, chip be opposite and 454 and 450 are considered to be similarly oriented or in the same direction. By offsetting and joining the SDRAM chips 402 and 404, in this case bonding with an adhesive layer 406, and electrically coupling 408 the chips 402 and 404 from the first pad 412 to the second pad 414, multiple advantages exist. It should be recognized that the two chips 402 and 404 are not required to be fixedly connected or attached when oriented in a stacked position. One advantage is ease of manufacturing and another is to make connections 410 from one controller (shown in FIG. 5) to both SDRAM chips 402 and 404. In this embodiment, the two SDRAM chips 402 and 404 are connected together 408 and with the SDRAMs 402 and 404 configured in such a way that the two SDRAMs 402 and 404 form a virtual single SDRAM from the controller's perspective. The benefit of this configuration is that there is twice the SDRAM in substantially the same footprint, or chip size area, as one SDRAM. This addresses the growing need for increased buffer memory and the increased pressure to minimized area space on a PCBA 302.

FIG. 4B shows a cross-sectional view of an alternative embodiment of FIG. 4. A first SDRAM 402 is stacked and offset relative a second SDRAM 404 with an adhesive layer 406 bonding the two together. The SDRAMs 402 and 404 are similarly oriented with the connection pads 412 and 414 in the direction indicated by 460. There is an electrical connection 430 coupling the first bonding pad 412 to an intermediate connection 438, or in this case an intermediate bonding pad, external from the SDRAMs 402 and 404. There is an electrical connection 432 coupling the second bonding pad 412 to the intermediate connection 438. The common intermediate connection 438, which electrically couples the two stacked SDRAMs 402 and 404, can support connections, such as 436, to other devices, such as the SoC 502. The stacked SDRAM 400 can be packaged as an MCP alone or can be combined with other chips, like the SoC 502, in a more diversified MCP.

FIG. 4C shows a cross-sectional view of three stacked dice, 404 on the bottom, 402 in the middle and 426 on the top. All of the dice are offset with the top die 426 electrically coupled to the middle die 402 by a wire 428. In this case, the top die 426 is joined to the middle die 402 by an adhesive layer 424. The chips 402, 404 and 426 are oriented such that the connection points 429, 412 and 414 are in the same direction, and in this case in the direction 460.

FIG. 5A shows a face view of the two SDRAMs 402 and 404 of FIG. 4A not stacked. The SDRAMs 402 and 404 are aligned by the respective edges 526 and 522 along the dotted line 524. In the case of chip 404, the connection pads 414 are along one edge of the chip located at the leading edge 416.

FIG. 5B shows an embodiment of the connections in a face view perspective of the stacked SDRAM 400 electrically connected to a chip having controller/channel functions 502 referred to as a SoC (System on Chip). As shown in this image, the electrical connection locations, or bonding pads in this case, as exemplified by elements 412 and 414 from the SDRAM chips 402 and 404 are all oriented in the same direction. The bottom SDRAM 402 is electrically connected to the top SDRAM 404 by connections such as that shown in 408. In this embodiment, the two SDRAMs 402 and 404 are identical and aligned with the pads, such as 412 and 414, along one edge. The connection pads, for example 412, serve the purposes described below.

There are shared non isolated grounds 556 in addition to isolated grounds 562 for improved noise immunity. The SDRAM system 400 is powered by +3.3V lines 558 as well as isolated power 560 for improved noise immunity. There are 32 data input/output lines per chip, 404 for example, represented by two groups 564 and 508. The data input/output lines 564 transfer data to data banks, or partitions of data, within the SDRAMs 402 and 404 where data are stored. These data input/output lines 564 are connected directly to the SoC 502 from the bottom SDRAM 402. The data input/output lines 508 are connected to the SoC 502 from the top SDRAM 404. The data input/output lines 564 and 508 are controlled by data input/output masks 566 and 590 respectively. The Bank Select 572 defines to which bank commands such as bank activate, reading, writing, and associated activities are being applied. There are 13 address lines 504 which are responsible for selecting the location for data inputs in the data banks. The clock 576, typically driven by the system clock, increments the internal burst counter and controls the output registers. Reading, writing, standby, and other commands input to the address lines 504 and 572 are controlled by the pads grouped in 578. The stacked chip set 400 is enabled to function as one chip if the Optional Stack pad 596 is couple together on both SDRAM's 402 and 404. Alternatively, one chip, such as 402, could be used in isolation with the SoC 504 if all of the pads 414 described above are coupled with the SoC 504. This would be desirable if double memory was not required. Finally, the stacked chips 400 can be examined for performance with test pads 594.

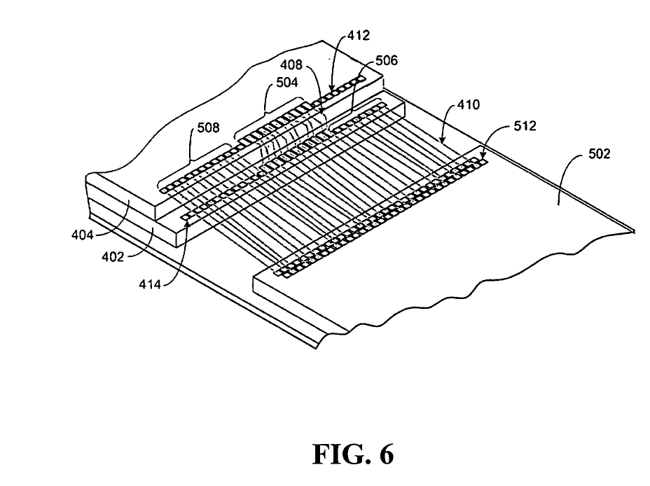

FIG. 6 is an isometric cut-away view of the embodiment shown in FIG. 5. In this example the dice 402 and 404 are shown to have electrical connections 412 and 414 located on a single surface of each die 402 and 404 and are oriented in the same direction. This facilitates ease in manufacturing for both the dice 402 and 404 and connections together 408.

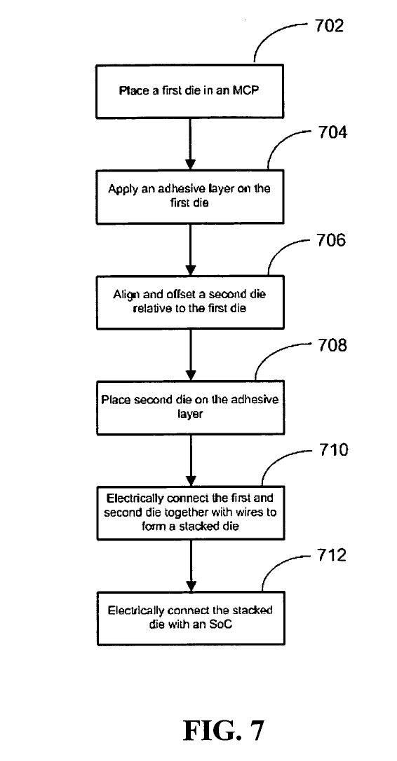

FIG. 7 illustrates the advantage of manufacturing in a method of the above embodiment; reference will be made to FIG. 4-6. Dice 402, 404 and 502 are shown, with dice 402 and 404 having their respective bonding pads 414 and 412 on one surface oriented in the same direction. The dice can have bonding pads, or bonding locations, on other edges, but the pads that are electrically coupled together are oriented in the same direction on each die. Such edges of dice 416 and 418 are aligned in an offset position as shown in FIG. 4. A manufacturing process as shown in FIG. 7 includes placing a first die, such as 404, in an MCP as shown in block 702. An adhesive layer is applied, such as 406, to the first die as shown in block 704, and then a second die, such as 402, is aligned and offset relative to the first die as shown in block 706. Block 708 shows the step of placing the second die on the adhesive layer and block 710 shows the step of electrically connecting the first die and the second die together with wires, such as 408, to form a stacked die, such as 400. The stacked die can then be electrically connected, such as 410, with an SoC, such as 502, to form the MCP. The steps described in FIG. 7 are not required to be in this order.

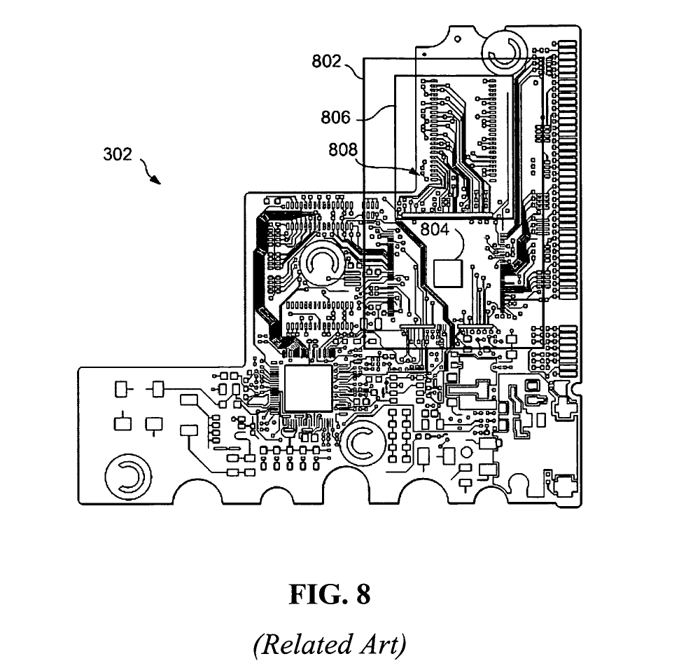

Referring now to FIG. 8, a PCBA 302 having multiple packages for use in a hard disc drive 300 is shown. Region 802 identifies the area of PCBA 302 where the die for the controller/channel functions and the die for the buffer function are placed. Area 804 shows the placement of the die for the controller/channel functions. It is noted that connections 808 are positioned between area 804 and area 806 to allow communication between the buffer function and the controller/channel functions. These connections introduce significant performance degradation.

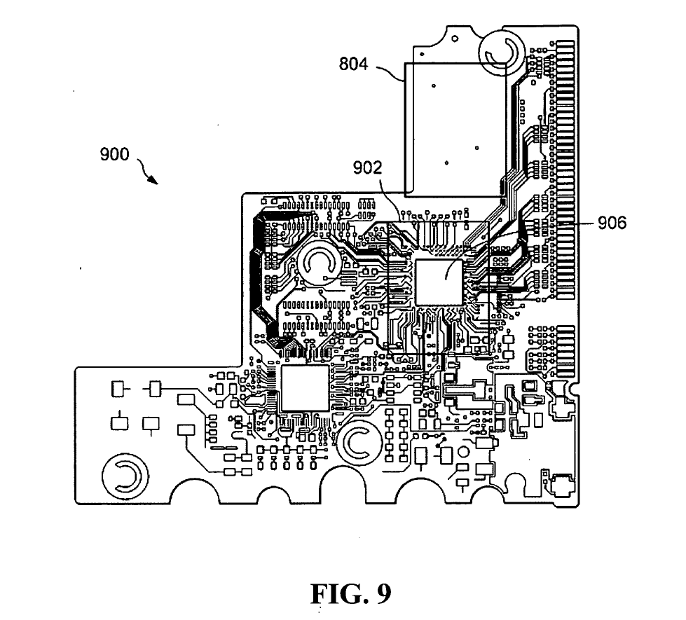

FIG. 9 shows an innovative PCBA 900 consistent with implementation in an embodiment of the present invention. PCBA 900 may be used in the hard disc drive 300 in FIG. 3. Area 502 shows the location for an MCP 906 that combines the functions of the stacked buffer 400, and the channel and controller functions 502. Area 804 shows the space savings achieved by combining the dice 502 and 400 in one package for placement on PCBA 900. Not only is space 804 saved, but the number of connections between the SoC 502 and the stacked SDRAM 400 is reduced, improving performance and reducing noise.

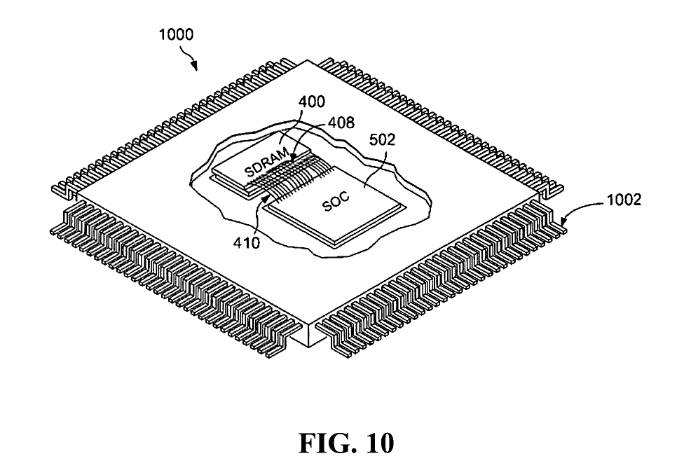

FIG. 10 shows a cutaway view of an innovative package, MCP 906, according to an embodiment of the present invention. Though the buffer, controller, and channel functions may be integrated into a single monolithic die, such a solution suffers from difficulty in testing, and costly reproduction of the entire die (with all three functions thereon) when one of the functions fails to work properly. Monolithic die with these functions are also proportionately more expensive to produce.

In FIG. 10, the integrated circuit package 906 is a dual e-pad Thin Flat Pack (TFP) package in this illustrative example. Other types of packaging are also consistent with this embodiment of the present invention, such as a Ball Grid Array (BGA) that attaches to the PCBA 900 using a series of solder bumps. In the example of FIG. 10, the SDRAM die 400 is shown next to the SOC 502. Connections leads 410 are used to connect the stacked SDRAM 400 with the SOC die 502. Such connection leads within a single package are shorter than the required connections leads between separately packaged dice, which must be placed at different locations on a PCBA such as in 302.

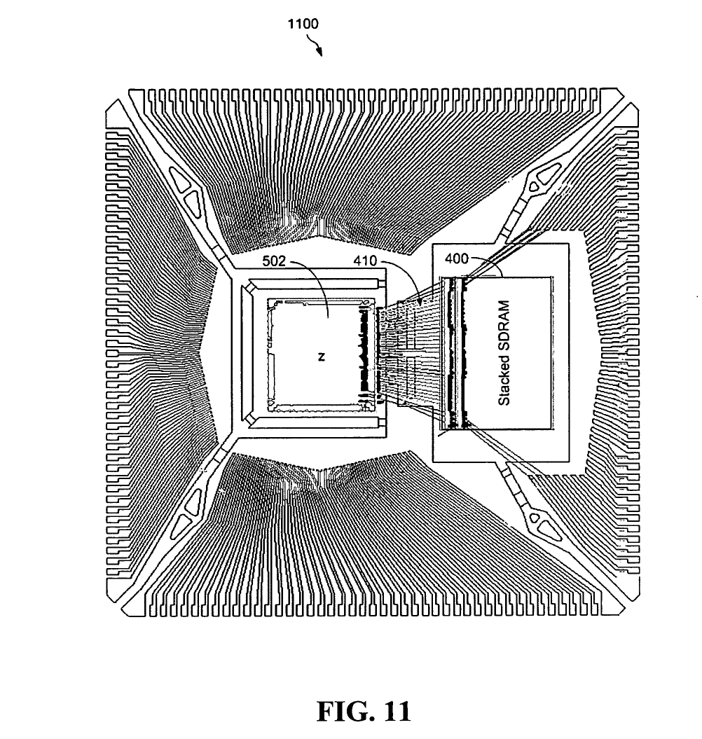

FIG. 11 shows an innovative MCP 1100 according to an embodiment of the present invention. MCP 1100 includes three dice, SoC 502 and the stacked SDRAMs 400. Connections, such as example connections 410, connect relevant locations on each die, SoC 502 and stacked SDRAM 400, to one another and are packaged in the MCP 1100. The pins, such as 1002, connect the MCP 1100 and the PCBA 900.

The present invention therefore provides a unique method and apparatus for stacking dice directed, but not limited, for use in an MCP. The present invention as applied to buffer memory eliminates connections between independently packaged dice, increases space available on a PCBA, improves performance by reducing noise and required signal strength between the buffer function dice and the controller/channel die. The present invention utilizes increases buffer memory in an advantageous streamline structure.

The foregoing description of the invention has been presented for purposes of illustration and description. It is not intended to be exhaustive or to limit the invention to the precise form disclosed, and other modifications may be possible in light of the above teachings. The embodiment was chosen and described in order to best explain the principles of the invention and its practical application to thereby enable others skilled in the art to best utilize the invention in various embodiments and various modifications as are suited to the particular use contemplated. It is intended that the appended claims be construed to include other alternative embodiments of the invention except insofar as limited by the prior art.

1. An apparatus comprising:
at least two dice;
each of said dice having at least one electrical connection disposed on a single surface;
said dice electrically coupled with at least one connector between said electrical connections that are oriented in the same direction when said dice are stacked and offset.

2. The apparatus of claim 1 wherein said dice are identical.

3. The apparatus of claim 1 wherein said at least one electrical connection is disposed on only one surface.

4. The apparatus of claim 1 wherein said dice are aligned.

5. The apparatus of claim 1 wherein said dice are attached.

6. The apparatus of claim 5 wherein said dice are attached with adhesive.

7. The apparatus of claim 1 wherein said dice are memory.

8. The apparatus of claim 1 wherein said dice are synchronous dynamic random access memory.

9. The apparatus of claim 7 wherein said synchronous dynamic random access memory is electrically coupled to a die having channel and controller functions.

10. The apparatus of claim 8 wherein said synchronous dynamic random access memory is packaged in a single package with said die having channel and controller functions.

11. The apparatus of claim 1 wherein said electrical connections from one die to another are made through intermediate electrical connections external from said dice.

12. The apparatus of claim 1 wherein said electrical connections are disposed on one edge.

13. The apparatus of claim 1 wherein said apparatus comprises a storage device.

14. An apparatus comprising:
at least two dice;
each of said dice having a plurality of electrical connections disposed on only one surface;
said dice stacked and offset with said electrical connections oriented in the same direction;
said dice are electrically coupled with at least one electrical connector.

15. The apparatus of claim 14 wherein said dice are identical.

16. The apparatus of claim 14 wherein said dice are aligned.

17. The apparatus of claim 14 wherein said dice are attached.

18. The apparatus of claim 17 wherein said dice are attached with adhesive.

19. The apparatus of claim 14 wherein said electrical connections are disposed on one edge.

20. The apparatus of claim 14 wherein said dice are memory.

21. The apparatus of claim 14 wherein said dice are synchronous dynamic random access memory.

22. The apparatus of claim 21 wherein said synchronous dynamic random access memory is electrically coupled to a die having channel and controller functions.

23. The apparatus of claim 21 wherein said synchronous dynamic random access memory is packaged in a single package with said die having channel and controller functions.

24. The apparatus of claim 14 wherein said electrical connections from one die to another are made through intermediate electrical connections external from said dice.

25. A method comprising:
placing a first die having electrical connections disposed on one surface in a first area of a package;
applying an adhesive layer on said first die;
aligning a second die having electrical connections disposed on one surface;
orienting said electrical connections on said first die and on said second die in a same direction;
offsetting said second die relative to said first die;
placing said second die on said adhesive layer;
electrically coupling said electrical connections that are oriented in said same direction on said first die and said second die.

26. The method of claim 25 further comprising electrically connecting said first die and said second die to a third die wherein said third die includes a controller function and a channel function for a disc drive.

27. The method of claim 25 further comprising packaging said first die and said second die in a single package.

28. The method of claim 25 further comprising packaging said first die, said second die and said third die in a single package.
